(19) United States
(12) Patent Application Publication
(10) Pub. No.: US 2025/0178845 A1
(43) Pub. Date: Jun. 5, 2025

(54) APPARATUS AND METHOD FOR HANDLING CARRIER RINGS MOUNTED WITH ELECTRONIC DEVICES

(71) Applicant: ASMPT Singapore Pte. Ltd., Singapore (SG)

(72) Inventors: Chak Tong SZE, Hong Kong SAR (CN); Pei Wei TSAI, Hong Kong SAR (CN); Wing Sze CHAN, Hong Kong SAR (CN); Wah Chun CHAN, Hong Kong SAR (CN)

(21) Appl. No.: 18/529,013

(22) Filed: Dec. 5, 2023

(51) Int. Cl. B65G 47/90; H01L 21/677; H01L 21/687; H01L 33/00

(52) U.S. Cl. CPC B65G 47/90; H01L 21/67721; H01L 21/67769; H01L 21/68707; H10H 20/80

(57) ABSTRACT

Electronic devices which are to be supplied to a bonder for bonding are mounted on carrier rings, and the carrier rings are stored in a storage bins station including a plurality of bin slots. A transfer arm is translatable alongside the plurality of bin slots for accessing the carrier rings supported by the bin slots. The transfer arm is further movable between a bin ring position located at a bin slot and an exchange ring position. An exchange arm assembly is movable between the exchange ring position whereat it picks up carrier rings from or places carrier rings onto the transfer arm, and a device supplying platform whereat the bonder is configured to receive the electronic devices supplied from the carrier ring.

### FIELD OF THE INVENTION

The invention relates to the bonding of electronic devices, and in particular to the efficient handling of carrier rings on which the electronic devices have been mounted when they are supplied for bonding operations.

### BACKGROUND AND PRIOR ART

When bonding electronic devices using a bonding apparatus in the semiconductor packaging industry, such as a die bonding machine, the electronic devices are typically mounted on carrier rings for bulk processing. The electronic devices in the form of processed semiconductor dies or chips are introduced while mounted on carrier rings as input. Such a carrier ring may be a wafer ring on which a wafer has been mounted and then singulated into individual dies, for instance light-emitting diode (“LED”) dies. Pick arms are then used for sequentially picking up the electronic devices from the supply of electronic devices mounted on the carrier ring at one location, and the electronic devices are bonded onto a substrate at another location.

In current storage bins for storing and supplying a plurality of such carrier rings, a small magazine is provided to store multiple carrier rings. Each carrier ring is supported on an adaptor ring plate inside the magazine. A movable gripper is used to pull each adaptor ring plate supporting each carrier ring out of the magazine, and the carrier ring is placed onto another platform to provide electronic devices to the bond head.

In such conventional designs, the magazines are relatively small so that they can be supported on a table next to the bond head. As such, they can only hold a limited number of carrier rings. The limited size of such a storage magazine adversely affects the productivity of the bonding apparatus, as the magazine needs to be manually replaced more often to insert fresh supplies of electronic devices. This is especially so when the electronic devices are LED devices, and the bonding apparatus is configured to bond multiple bin grades of LED devices. Moreover, since only one movable arm is provided to pick and place one carrier ring at a time for use by the bond head, this leads to slow carrier ring exchange operations.

In order to optimize the productivity of the bonding apparatus or bonder, it would be beneficial to provide a larger storage capacity to hold a greater number of carrier rings. The increased capacity to store more carrier rings would be particularly useful for bonding multiple grades of LED devices from different bins onto a substrate. Besides the greater number of carrier rings that can be stored, productivity can be further improved by simultaneously supplying and retrieving carrier rings from a device supplying platform. Achieving fast exchanges of carrier rings can significantly reduce changeover time. As such, the above limitations of conventional carrier ring transfer systems can be avoided.

### SUMMARY OF THE INVENTION

It is thus an object of the invention to seek to provide an apparatus for handling carrier rings which is capable of storing an increased number of carrier rings. Further, it would also be beneficial to provide a carrier ring handler that has an increased efficiency in carrier ring transfer operations to increase the throughput of the bonding machine.

According to a first aspect of the invention, there is provided an apparatus for supplying electronic devices mounted on a carrier ring to a bonder for bonding the electronic devices, the apparatus comprising: a storage bins station including a plurality of bin slots, each bin slot being configured for supporting a carrier ring; a transfer arm that is translatable alongside the plurality of bin slots so as to access the carrier rings supported by the bin slots, the transfer arm being further movable between a bin ring position and an exchange ring position, the bin ring position being located at a bin slot whereat the transfer arm is operative to pick up a carrier ring from the bin slot or to place a carrier ring into the bin slot; and an exchange arm assembly which is movable between the exchange ring position and a device supplying platform whereat the bonder is configured to receive the electronic devices supplied from the carrier ring, the exchange arm assembly being operative to pick up the carrier ring from or place the carrier ring onto the transfer arm at the exchange ring position, and to pick up the carrier ring from or place the carrier ring onto the device supplying platform.

According to a second aspect of the invention, there is provided a method for supplying electronic devices mounted on a carrier ring to a bonder for bonding the electronic devices, the method comprising the steps of: providing a storage bins station including a plurality of bin slots, each bin slot being configured for supporting a carrier ring; translating a transfer arm alongside the plurality of bin slots so as to access the carrier rings supported by the bin slots; moving the transfer arm to a bin ring position located at a bin slot to pick up a carrier ring from the bin slot, and then moving the carrier ring with the transfer arm to an exchange ring position; moving an exchange arm assembly to the exchange ring position to pick up the carrier ring from the transfer arm and then moving the carrier ring with the exchange arm assembly to a device supplying platform; and receiving with the bonder the electronic devices supplied from the carrier ring located at the device supplying platform.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

An example of an apparatus and method for handling carrier rings in accordance with the invention will now be described with reference to the accompanying drawings, in which:

FIG. 1 is an isometric view of a storage bins station according to an embodiment of the invention;

FIG. 2 is a side view of a transfer arm according to an embodiment of the invention picking up a carrier ring from a bin slot at the storage bins station;

FIG. 3 shows isometric views of a transfer arm having an empty transfer arm ring carrier and the transfer arm ring carrier supporting a carrier ring respectively;

FIG. 4A is a plan view of the transfer arm moving from a standby position to a bin ring position to pick up a carrier ring, and FIG. 4B is a plan view of the transfer arm moving the carrier ring that has been picked up from the bin ring position back to the standby position;

FIG. 5 is a plan view of an exchange ring position, a standby position and a bin ring position of the transfer arm relative to the storage bins station;

FIG. 6 is an isometric view of an exchange arm assembly according to an embodiment of the invention for transferring carrier rings between the exchange ring position and a device supplying platform;

FIG. 7 is a plan view showing relative positions of the storage bins station, transfer arm, exchange arm assembly and a bond head according to an embodiment of the invention; and

FIG. 8A is a plan view of the transfer arm moving from the standby position to the bin ring position to place a carrier ring into the bin slot, and FIG. 8B is a plan view of the transfer arm moving from the bin ring position back to the standby position after having placed the carrier ring into the bin slot.

### DETAILED DESCRIPTION OF THE PREFERRED EMBODIMENTS OF THE INVENTION

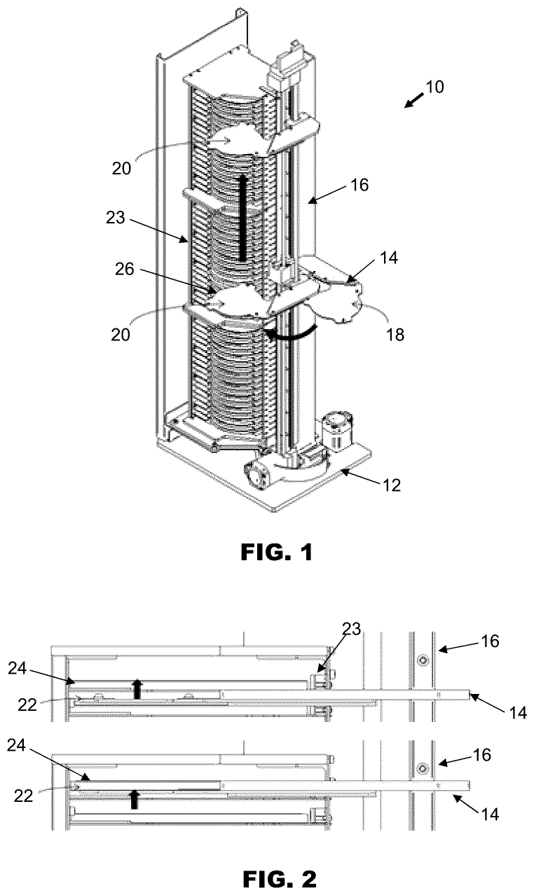

FIG. 1 is an isometric view of a storage bins station 10 according to an embodiment of the invention. The storage bins station 10 has a plurality of bin slots 23, each bin slot 23 being configured for supporting a carrier ring 24. Different from conventional designs that provide only a limited number of storage bins for storing and supplying carrier rings, the storage bins station 10 is capable of storing a large number of carrier rings 24, such as more than eighteen bin slots 23 for storing a corresponding number of carrier rings 24. In the illustrated embodiment, fifty-four bin slots 23 for storing up to fifty-four carrier rings 24 is shown. Therefore, to cater for the large capacity, the storage bins station 10 may have a base 12 that is resting on a production floor separately from a bonder for accommodating the large number of stacked bin slots 23 next to the bonder, instead of being supported on a table next to the bond head of the bonder like in conventional designs.

A movable transfer arm 14 is mounted alongside the storage bins station 10 in order to access the large number of carrier rings 24 supported by the bin slots 23 and stacked within the storage bins station 10. Translation of the transfer arm 14 alongside the plurality of bin slots 23 is guided by a vertical linear guide 16 that allows the transfer arm 14 to access all the carrier rings 24 that are stacked within the storage bins station 10. Besides vertical motion along the vertically-oriented linear guide 16, the transfer arm 14 is also capable of horizontal motion while it is being actuated to move in a rotary motion. In particular, the transfer arm 14 is movable between an exchange ring position, a bin ring position 22, and a standby position 20 which is situated at an intermediate position between the exchange ring position 18 and the bin ring position 22 (see FIG. 2).

In FIG. 1, the transfer arm 14 is illustrated by the bold arrows as rotating from its exchange ring position 18 to its standby position 20, and then moving upwards along the linear guide 16 to a height of a target carrier ring. Accordingly, the transfer arm 14 is translated alongside the plurality of bin slots 23 while the transfer arm 14 is in the standby position 20. Once the transfer arm 14 arrives at the targeted vertical position, its transfer arm ring carrier 26 is rotated from the standby position 20 to the bin ring position 22 underneath the target carrier ring 24 at a selected bin slot 23, so as to retrieve and pick up the target carrier ring 24 from the selected bin slot 23. Besides rotational motion of the transfer arm 14, it should be appreciated that other motions may be adopted for the transfer arm 14, such as actuating linear motion of the transfer arm 14 between the exchange ring position 18, standby position 20 and bin ring position 22 instead.

FIG. 2 is a side view of a transfer arm 14 according to an embodiment of the invention picking up a carrier ring 24 from a bin slot 23 at the storage bins station 10. At the top of FIG. 2, the transfer arm 14 has been translated while being guided by the linear guide 16 to a height of a target carrier ring 24 that has been slotted into one of the plurality of bin slots 23. The transfer arm ring carrier 26 is positioned at the bin slot position 22 underneath the target carrier ring 24 to pick it up from the relevant bin slot 23. At the bottom of FIG. 2, the transfer arm 14 is lifted to support and raise the target carrier ring 24 with the transfer arm ring carrier 26 at the bin ring position 22, before carrying the carrier ring 24 away from the bin slot 23.

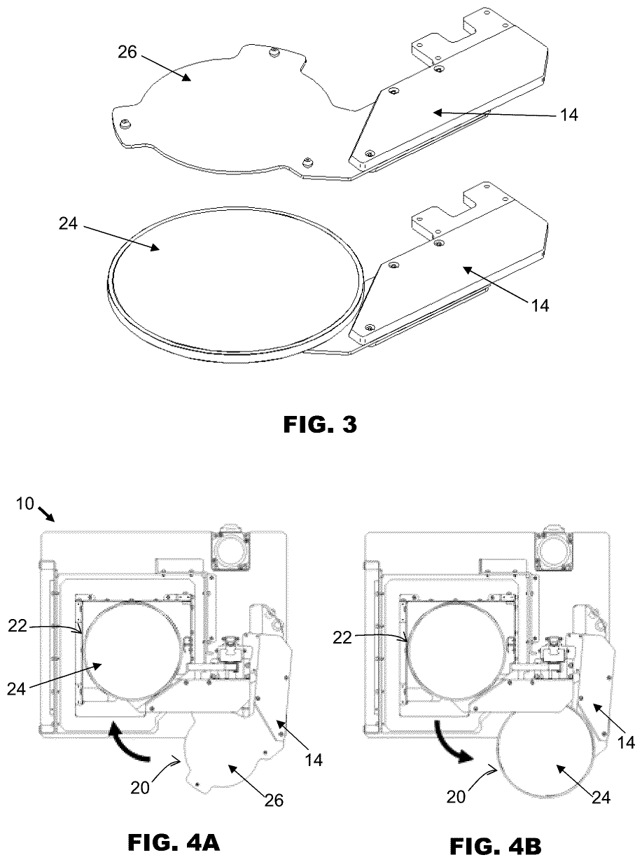

The top of FIG. 3 shows an isometric view of the transfer arm ring carrier 26 of the transfer arm 14 when it is empty and not supporting a carrier ring 24. The bottom of FIG. 3 shows an isometric view of the transfer arm ring carrier 26 that is supporting a carrier ring 24. In the latter state, the carrier ring 24 may be moved between the said exchange ring position 18, standby position 20 and bin ring position 22 of the transfer arm 14 either by rotary or linear motion.

FIG. 4A is a plan view of the transfer arm 14, and particularly its transfer arm ring carrier 26, moving from the standby position 20 to the bin ring position 22 to pick up a carrier ring 22. When the transfer arm 14 is moved to the bin ring position 22, its transfer arm ring carrier 26 is located underneath a target carrier ring 24. Thereafter, the transfer arm 14 moves upwards to lift the carrier ring 24 so that the carrier ring 24 is no longer supported by the bin slot 23.

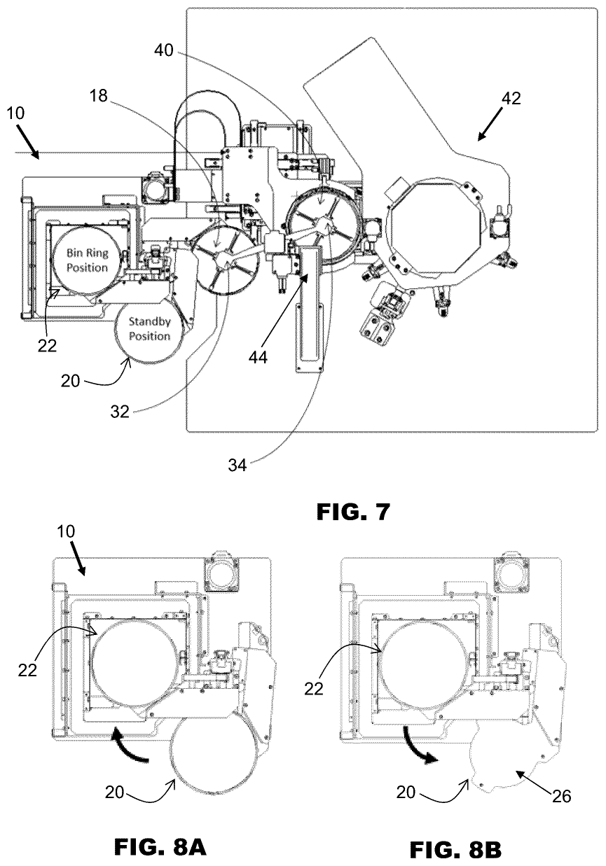

FIG. 4B is a plan view of the transfer arm 14 that is supporting the raised carrier ring 24 moving the carrier ring 24 that has been picked up from the bin ring position 22 back to the standby position 20. At the standby position 20 of the transfer arm 14, the transfer arm 14 is raised or lowered as necessary to convey the carrier ring 24 to a location of an exchange ring position 18 for supply of the electronic devices mounted on the carrier rings 24 to a bond head 42 (see FIG. 7).

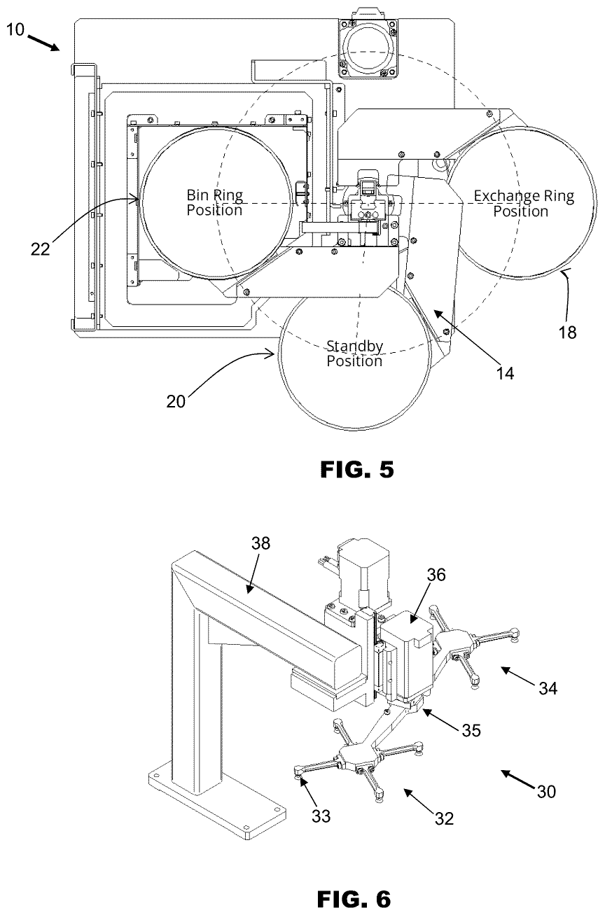

FIG. 5 is a plan view of the exchange ring position 18, the standby position 20 and the bin ring position 22 of the transfer arm 14 relative to the storage bins station 10. It should be appreciated that although the standby and bin ring positions 20, 22 may be located at various heights depending on a height of a target carrier ring 24 and corresponding bin slot 23 supporting it, the exchange ring position 18 is typically located at a fixed height where conveyance of the carrier ring 24 to other platforms should take place.

FIG. 6 is an isometric view of an exchange arm assembly 30 according to an embodiment of the invention for transferring carrier rings 24 from the exchange ring position 18 to a device supplying platform 40 (see FIG. 7), and from the device supplying platform 40 to the exchange ring position 18. The exchange arm assembly 30 generally includes at least two exchange tools, namely a first exchange tool 32 and a second exchange tool 34 that are located on opposite sides of a pivot point 35 that is situated between the exchange ring position 18 and the device supplying platform 40. The first and second exchange tools 32, 34 are configured to be contemporaneously rotatable about the pivot point 35 between the exchange ring position 18 and the device supplying platform 40. Each of the first and second exchange tools 32, 34 has a plurality of gripping fingers 33 for the purpose of holding onto sides of a carrier ring 24.

The first and second exchange tools 32, 34 are actuable to rotate by a rotary mechanism 35 to rotate about the pivot point 35, with the first and second exchange tools being located on opposite sides of the pivot point 35. The exchange arm assembly 30 and rotary mechanism 36 are both mounted on an exchange arm assembly support 38. The benefit of having more than one exchange tool 32, 34 in the exchange arm assembly 30 is that productivity is improved since a carrier ring 24 may be transferred for bonding at the same time as another, used, carrier ring 24 is being conveyed back to the storage bins station 10 for storage. After rotation thereof, the first and second exchange tools 32, 34 are further movable towards the transfer arm 14 for placing a carrier ring 24 onto the transfer arm 14, or for picking up a carrier ring 24 from the transfer arm 14.

FIG. 7 is a plan view showing relative positions of the storage bins station 10, transfer arm 14, exchange arm assembly 30 and a bond head 42 according to an embodiment of the invention. Starting from the bin ring position 22 of the transfer arm 14 within the storage bins station 10, the transfer arm 14 is drivable to rotate while carrying the carrier ring 24 to the standby position 20. The transfer arm 14 is then vertically moved along the linear guide 16 while carrying the carrier ring 24 to a height of the exchange ring position 18. The transfer arm 14 is then drivable to rotate to the exchange ring position 18.

Each of the first and second exchange tools 32, 34 of the exchange arm assembly 30 is reciprocally rotatable between the exchange ring position 18 and the device supplying position 40. When the carrier ring 24 is brought to the exchange ring position 18, the exchange arm assembly 30 moves down towards the carrier ring 24 held on the transfer arm ring carrier 26. The gripping fingers 33 of the first or second exchange tool 32, 34 that is located over the carrier ring 24 will close onto a perimeter of the carrier ring 24 to grip the carrier ring 24. The first and second exchange tools 32, 34 are then moved upwards and are rotated to swap positions so that the carrier ring 24 is now located over the device supplying platform 40 that is located opposite to the exchange ring position 18 about the pivot point 35. At this time, the other exchange tool 32, 34 may simultaneously pick up a new carrier ring 24 from the transfer arm ring carrier 26 while one exchange tool 32, 34 is placing a carrier ring 24 onto the device supplying platform 40.

Thereafter, during a next rotation of the exchange arm assembly 30, an unused carrier ring 24 can be picked up and transferred to the device supplying platform 40 while a used carrier ring 24 can be picked up and transferred to the transfer arm ring carrier 26 simultaneously, thereby increasing throughput as compared with having only one exchange arm to conduct such transfers.

The device supplying platform 40 is located adjacent to a bond head 42 of the bonder, so that electronic devices such as LED components are accessible to be received and picked up by the bond head 42 from the carrier ring 24 to be used for bonding onto a substrate that is at the position underneath the bond head 42. An imaging camera 44 may be located over the device supplying platform 40 for identifying positions of individual electronic devices to be picked up, as well as for inspecting the presence or absence of electronic devices at predetermined positions on the carrier ring 24.

Once all or a desired number of electronic devices have been picked from the carrier ring 24 for bonding, the used carrier ring 24 is gripped by the first or second exchange tool 32, 34, and the first and second exchange tools 32, 34 are rotated for placing the used carrier ring 24 back onto the transfer arm 14 at the exchange ring position 18. Moving in the reverse direction, the used carrier ring 24 is subsequently placed back into an empty bin slot 23 at the storage bins station 10.

FIG. 8A is a plan view of the transfer arm 14 moving from the standby position 20 to the bin ring position 22 to place the used carrier ring 24 back into the empty bin slot 23. At the bin ring position 22, the transfer arm ring carrier 26 is carrying the carrier ring 24 slightly over a support of the bin slot 23. The carrier ring 24 is then lowered so that it is supported on the bin slot 23.

After placing the carrier ring 24 in the bin slot 23, the transfer arm 14 may move back to its standby position 20. FIG. 8B is a plan view of the transfer arm 14 moving from the bin ring position 22 back to the standby position 20 after having placed the carrier ring 24 into the bin slot. Thereafter, the transfer arm 14 may be moved vertically in upward or downward directions at the standby position 20 to pick up another carrier ring 24 at the bin ring position 22, and thereafter transfers the carrier ring 24 to the exchange bin position 18.

It should be appreciated that the relatively larger capacity of the storage bins station 10 optimizes the productivity of the device bonder and increases its efficiency, especially when there is a need to bond electronic devices from multiple grades of electronic devices from different bins. The described embodiment of the invention includes a bin elevator with multiple slots, and an independently movable transfer arm which allows picking of the next carrier ring 24 in advance. This is effective for reducing the changeover time for new and used carrier rings 24.

Since the exchange arm assembly 30 includes more than one exchange tool 32, 34, the exchange arm assembly 30 is able to conduct the pick-up and placing of different carrier rings 24 simultaneously. This design is therefore able to significantly reduce the changeover time as compared with conventional systems.

The invention described herein is susceptible to variations, modifications and/or additions other than those specifically described and it is to be understood that the invention includes all such variations, modifications and/or additions which fall within the spirit and scope of the above description.

1. An apparatus for handling electronic devices mounted on a carrier ring to be supplied to a bonder for bonding the electronic devices, the apparatus comprising:
a storage bins station including a plurality of bin slots, each bin slot being configured for supporting a carrier ring;
a transfer arm that is translatable alongside the plurality of bin slots so as to access the carrier rings supported by the bin slots, the transfer arm being further movable between a bin ring position and an exchange ring position, the bin ring position being located at a bin slot whereat the transfer arm is operative to pick up a carrier ring from the bin slot or to place a carrier ring into the bin slot; and
an exchange arm assembly which is movable between the exchange ring position and a device supplying platform whereat the bonder is configured to receive the electronic devices supplied from the carrier ring, the exchange arm assembly being operative to pick up the carrier ring from or place the carrier ring onto the transfer arm at the exchange ring position, and to pick up the carrier ring from or place the carrier ring onto the device supplying platform.

2. The apparatus as claimed in claim 1, further comprising a linear guide for guiding the transfer arm while it is translated alongside the plurality of bin slots for accessing the carrier rings supported by the bin slots.

3. The apparatus as claimed in claim 2, wherein the linear guide is oriented vertically while the bin ring position and exchange ring position of the transfer arm are horizontally spaced apart at the exchange ring position.

4. The apparatus as claimed in claim 1, further comprising a standby position of the transfer arm which is situated at an intermediate position between the bin ring position and the exchange ring position, wherein the transfer arm is translated alongside the plurality of bin slots while the transfer arm is in the standby position.

5. The apparatus as claimed in claim 1, wherein the transfer arm is movable between the bin ring position and the exchange ring position while being actuated to move in a rotary motion.

6. The apparatus as claimed in claim 1, wherein the transfer arm includes a transfer arm ring carrier for lifting and supporting the carrier ring at the bin ring position when the transfer arm picks up the carrier ring from the bin slot.

7. The apparatus as claimed in claim 6, wherein the transfer arm ring carrier is located underneath the carrier ring when it is at the bin ring position for lifting the carrier ring.

8. The apparatus as claimed in claim 1, wherein the bin ring positions are located at multiple heights corresponding to heights of the plurality of bin slots, and the exchange ring position is located at a fixed height for conveyance of the carrier ring from the exchange ring position to the device supplying platform.

9. The apparatus as claimed in claim 1, wherein the exchange arm assembly includes a first exchange tool and a second exchange tool that are located on opposite sides of a pivot point and are rotatable about the pivot point, the pivot point being situated between the exchange ring position and the device supplying platform.

10. The apparatus as claimed in claim 9, wherein each of the first and second exchange tools has a plurality of gripping fingers for holding onto sides of the carrier ring.

11. The apparatus as claimed in claim 9, further comprising an exchange arm assembly support on which the exchange arm assembly is mounted, and a rotary mechanism mounted on the exchange arm assembly support that is operative to rotate the first and second exchange tools about the pivot point.

12. The apparatus as claimed in claim 9, wherein the first and second exchange tools are further movable towards the transfer arm for placing the carrier ring onto the transfer arm or for picking up the carrier ring from the transfer arm.

13. The apparatus as claimed in claim 9, wherein the first and second exchange tools are rotatable to swap positions to simultaneously transfer a first carrier ring carried by the first exchange tool from the exchange bin position to the device supplying platform, and a second carrier ring carried by the second exchange tool from the device supplying platform to the exchange bin position.

14. The apparatus as claimed in claim 1, wherein the storage bins station comprises more than eighteen stacked bin slots.

15. The apparatus as claimed in claim 14, wherein the bonder is resting on a floor, and the storage bins station further comprises a base that is resting on the floor separately from the bonder for accommodating the more than eighteen stacked bin slots next to the bonder.

16. A method for supplying electronic devices mounted on a carrier ring to a bonder for bonding the electronic devices, the method comprising the steps of:
providing a storage bins station including a plurality of bin slots, each bin slot being configured for supporting a carrier ring;
translating a transfer arm alongside the plurality of bin slots so as to access the carrier rings supported by the bin slots;
moving the transfer arm to a bin ring position located at a bin slot to pick up a carrier ring from the bin slot, and then moving the carrier ring with the transfer arm to an exchange ring position;
moving an exchange arm assembly to the exchange ring position to pick up the carrier ring from the transfer arm and then moving the carrier ring with the exchange arm assembly to a device supplying platform; and
receiving with the bonder the electronic devices supplied from the carrier ring located at the device supplying platform.

17. The method as claimed in claim 16, further comprising moving the transfer arm to a standby position which is situated at an intermediate position between the bin ring position and the exchange ring position, prior to translating the transfer arm alongside the plurality of bin slots while the transfer arm is at the standby position.

18. The method as claimed in claim 16, wherein the exchange arm assembly includes a first exchange tool and a second exchange tool that are located on opposite sides of a pivot point that is situated between the exchange ring position and the device supplying platform, and the step of moving the carrier ring with the exchange arm assembly further comprises rotating the first and second exchange tools about the pivot point.

19. The method as claimed in claim 18, further comprising moving the first or second exchange tool towards the transfer arm to pick up the carrier ring from the transfer arm with the first or second exchange tool.

20. The method as claimed in claim 18, further comprising rotating the first and second exchange tools about the pivot point to swap positions so as to simultaneously transfer a first carrier ring carried by the first exchange tool from the exchange bin position to the device supplying platform, and a second carrier ring carried by the second exchange tool from the device supplying platform to the exchange bin position.
